(19) United States
(12) Patent Application Publication
(10) Pub. No.: US 2021/0269714 A1
(43) Pub. Date: Sep. 2, 2021

(54) YELLOW EMITTING LUMINOPHORE AND ILLUMINATING DEVICE

(71) Applicant: OSRAM OLED GmbH, Regensburg (DE)

(72) Inventors: Simon Peschke, Assling (DE); Philipp Schmid, Germering (DE); Thorsten Schroeder, Munich (DE)

(21) Appl. No.: 17/252,306

(22) PCT Filed: Jun. 5, 2019
(86) PCT No.: PCT/EP2019/064662

§ 371 Date: Dec. 15, 2020

(30) Foreign Application Priority Data
Jun. 15, 2018 (DE) 10 2018 004 827.7

(51) Int. Cl. C09K 11/77; C01B 21/082; H01L 33/50

(52) U.S. Cl. CPC C09K 11/77347; C01B 21/0823; H01L 33/502; H01L 33/32; C01P 2002/77; C01P 2002/72; C01P 2002/76

(57) ABSTRACT

A luminophore may have the general empirical formula X₃A₄Si₃O₈N₂:E, where:
X=Mg, Ca, Sr, Ba, Zn, or combinations thereof;
A=Li, Na, K, Rb, Cs, Cu, Ag, or combinations thereof;
Z=Al, Ga, B, or combinations thereof; and
E=Eu, Ce, Yb, Mn, or combinations thereof.

### CROSS-REFERENCE TO RELATED APPLICATIONS

The present application is a national stage entry according to 35 U.S.C. § 371 of PCT application No.: PCT/EP2019/064662 filed on Jun. 5, 2019; which claims priority to German Patent Application Serial No.: 10 2018 004 827.7 filed on Jun. 15, 2018; all of which are incorporated herein by reference in their entirety and for all purposes.

### TECHNICAL FIELD

The disclosure relates to a phosphor and to an illumination device that especially comprises the phosphor.

### BACKGROUND

White-emitting conversion LEDs typically use a semiconductor chip that emits a blue primary radiation and one or more phosphors that partly convert the primary radiation into secondary radiation. Overlap of the primary and secondary radiation results in white overall radiation from the conversion LED. The most practical solution is to use a blue-emitting semiconductor chip and only one, yellow-emitting phosphor. The human eye is able to perceive light from the blue to the red region of the spectrum, but is not equally sensitive across the entire range. Maximum eye sensitivity is at 555 nm. The greater the overlap of the overall radiation of a conversion LED with the eye sensitivity curve, the higher its luminous efficacy. The luminous efficacy can therefore serve as a measure of how efficiently a conversion LED emits visible radiation. The luminous efficacy of a phosphor can be determined via its emission spectrum. For “single-phosphor conversions” in particular, that is to say for conversion LEDs having only one phosphor, the luminous efficacy of the phosphor needs to be very high. In the yellow region of the electromagnetic spectrum only few efficient phosphors are thus far known.

Known yellow phosphors are (Y,Gd,Tb,Lu)₃Al₅O₁₂:Ce garnet phosphors. However, these have the disadvantage of very broad emission bands.

It is also possible to adjust the composition of phosphors of the general formula (Sr,Ba)Si₂O₂N₂:Eu so that they emit in the yellow region of the spectrum. These have narrower emission bands compared to garnet phosphors, but have poor long-term stability and are therefore the limiting factor in the service life of conversion LEDs that use these phosphors.

There is thus a need for efficient and stable phosphors that emit in the yellow region of the spectrum.

### SUMMARY

An object is to provide a phosphor that emits radiation in the yellow region of the spectrum. A further object is to specify an illumination device comprising the phosphor described herein.

This object/these objects are achieved by a phosphor and an illumination device as described in the independent claims. Advantageous embodiments and developments are the subject of the respective dependent claims.

A phosphor is specified. The phosphor has the general empirical formula X₃A₄Si₃O₈N₂:E, wherein
X=Mg, Ca, Sr, Ba, and/or Zn and
A=Li, Na, K, Rb, Cs, Cu, and/or Ag. The phosphor is doped with an activator E, wherein E=Eu, Ce, Yb, and/or Mn. More particularly, the activator is responsible for the emission of radiation from the phosphor.

Here and hereinbelow, phosphors are described on the basis of empirical formulas. In the stated empirical formulas, it is possible for the phosphor to include further elements, for example in the form of impurities, these impurities taken together optionally comprising a proportion by weight in the phosphor of not more than 1 part per thousand or 100 ppm (parts per million) or 10 ppm.

On excitation with primary radiation, the phosphors surprisingly exhibit an emission or secondary radiation having a peak wavelength or dominant wavelength in the yellow region of the spectrum and additionally exhibit a small full width at half maximum (FWHM), which is in particular less than 105 nm. The peak wavelength is optionally between 530 nm and 550 nm inclusive, such as between 535 nm and 545 nm inclusive.

The full width at half maximum is here and hereinbelow understood as meaning the spectral width at half the height of the maximum of an emission peak or emission band.

In at least one embodiment, E is at least Eu, such as at least Eu²⁺. Eu or Eu²⁺ may be combined with Ce, Yb, and/or Mn. For example, E=Eu or Eu²⁺.

The use of the activators Eu, Ce, Yb and/or Mn, in particular Eu or Eu in combination with Ce, Yb, and/or Mn, allows the color locus of the phosphor in the CIE color space (1931), the peak wavelength (λₚₑₐₖ) and dominant wavelength (λ_{dom}) thereof, and the full width at half maximum to be adjusted particularly readily.

The “peak wavelength” refers here to the wavelength in the emission spectrum of a phosphor at which the emission spectrum or an emission band shows maximum intensity.

The dominant wavelength is a means of describing non-spectral (polychromatic) light mixtures through spectral (monochromatic) light that produces a similar perception of hue. In the CIE color space, the line connecting a point for a specific color and the point CIE-x=0.333, CIE-y=0.333 can be extrapolated so that it meets the perimeter of the space at two points. The point of intersection that is closer to said color represents the dominant wavelength of the color as the wavelength of the pure spectral color at this point of intersection. The dominant wavelength is thus the wavelength that is perceived by the human eye.

In a further embodiment, the activator E may be present in mol % amounts of between 0.1 mol % to 20 mol %, 1 mol % to 10 mol %, 0.5 mol % to 5 mol %, 2 mol % to 5 mol %. If the concentration of E is too high, this can lead to a loss of efficiency due to concentration quenching. Here and hereinbelow, values in mol % for the activator E, in particular Eu, are understood as meaning in particular mol % based on the molar proportions of X in the respective phosphor.

In at least one embodiment, the phosphor has the general empirical formula X₃A₄Si₃O₈N₂:E, wherein
X=Mg, Ca, Sr, and/or Ba;
A=Li, Na, K, Rb, Cs, Cu, and/or Ag and
E=Eu, Ce, Yb, and/or Mn. The use of alkaline earth metals for X results in particularly stable and narrow-band phosphors.

In at least one embodiment, the phosphor has the general empirical formula X₃A₄Si₃O₈N₂:E, wherein
X=Mg, Ca, Sr, and/or Ba;
A=Li and
E=Eu, Ce, Yb, and/or Mn.

In at least one embodiment, the phosphor has the general empirical formula (Ca₁₋ₓX⁺ₓ)₃A₄Si₃O₈N₂:E, wherein
X⁺=Mg, Ba, and/or Sr;
A=Li, Na, K, Rb, Cs, Cu, and/or Ag;
E=Eu, Ce, Yb, and/or Mn and
0≤x≤1, such as 0≤x<1, or 0≤x≤0.5, or 0≤x≤0.25.

In at least one embodiment, the phosphor has the general empirical formula (Ca₁₋ₓX⁺ₓ)₃Li₄Si₃O₈N₂:E, wherein
X⁺=Mg, Ba, and/or Sr;
E=Eu, Ce, Yb, and/or Mn and
0≤x≤1, 0≤x<1, such as 0≤x≤0.5, or 0≤x≤0.25.

In at least one embodiment, the phosphor has the general empirical formula (Ca₁₋ₓX⁺ₓ)₃A₄Si₃O₈N₂:E, wherein
X⁺=Ba and/or Sr;
A=Li, Na, K, Rb, Cs, Cu, and/or Ag;
E=Eu, Ce, Yb, and/or Mn and
0≤x≤1, such as 0≤x<1, or 0≤x≤0.5, or 0≤x≤0.25.

In at least one embodiment, the phosphor has the general empirical formula (Ca₁₋ₓX⁺ₓ)₃A₄Si₃O₈N₂:E, wherein
X⁺=Mg, Ba, and/or Sr or
X⁺=Ba and/or Sr;
A=Li, Na, K, Rb, and/or Cs;
E=Eu, Ce, Yb, and/or Mn and
0≤x≤1, such as 0≤x<1, such as 0≤x≤0.5, or 0≤x≤0.25.

In at least one embodiment, the phosphor has the general empirical formula (Ca₁₋ₓX⁺ₓ)₃Li₄Si₃O₈N₂:E, wherein
X⁺=Ba and/or Sr;
E=Eu, Ce, Yb, and/or Mn and
0≤x≤1, such as 0≤x<1, or 0≤x≤0.5, or 0≤x≤0.25.

Varying the proportion of Ca in the phosphor advantageously allows the position of the peak wavelength to be influenced. In particular, phosphors having a high calcium content have been found to be particularly efficient and to have long-term stability.

In at least one embodiment, the phosphor is capable of absorbing primary radiation from the UV to blue region of the spectrum and converting it into secondary radiation that has a peak wavelength between 530 nm and 550 nm inclusive, such as between 535 nm and 545 nm inclusive. For excitation with primary radiation of 400 nm, the dominant wavelength may be in the region between 553 nm and 557 nm inclusive.

In addition, in at least one embodiment the phosphor has a full width at half maximum of between 85 nm and 105 nm inclusive, such as between 90 nm and 95 nm inclusive. It is possible for the full width at half maximum to vary according to the choice of wavelength of the primary radiation.

In at least one embodiment, the phosphor has the general empirical formula Ca₃A₄Si₃O₈N₂:E, wherein
A=Li, Na, K, Rb, Cs, Cu, and/or Ag, such as
A=Li, Na, K, Rb, and/or Cs and
E=Eu, Ce, Yb, and/or Mn.

In at least one embodiment, the phosphor has the general empirical formula Ca₃Li₄Si₃O₈N₂:E, wherein E=Eu, Ce, Yb, and/or Mn, such as E=Eu, or E=Eu²⁺.

On excitation with primary radiation from the UV to blue region of the spectrum, the phosphor Ca₃Li₄Si₃O₈N₂:Eu emits secondary radiation having a peak wavelength in the yellow region of the spectrum, in particular between 535 nm and 545 nm inclusive. Surprisingly, the emission band of the phosphor has a full width at half maximum of less than 105 nm and thus high luminous efficacy as a consequence of high overlap with the human eye sensitivity curve having a maximum at 555 nm. This allows the phosphor to provide particularly efficient illumination devices.

In at least one embodiment, the phosphor crystallizes in an orthorhombic crystal system. In a non-limiting embodiment, the phosphor crystallizes in the orthorhombic space group Pbcn.

The inventors have thus recognized that a novel phosphor having advantageous properties can be provided that could not previously be provided.

The process for producing the phosphor is very simple to execute compared to many other production processes for phosphors, for example compared to the production process for yellow garnet phosphors. In particular, the synthesis takes place at moderate temperatures and is therefore very energy-efficient. The demands placed e.g. on the furnace used are accordingly low. The starting materials are commercially available at low cost and are non-toxic.

The disclosure also relates to an illumination device. More particularly, the illumination device comprises the phosphor. All explanations and definitions relating to the phosphor likewise apply to the illumination device and vice versa.

In at least one embodiment, the illumination device includes a semiconductor layer sequence. The semiconductor layer sequence is configured for the emission of electromagnetic primary radiation.

In at least one embodiment, the semiconductor layer sequence includes at least one III-V compound semiconductor material. The semiconductor material is, for example, a nitride compound semiconductor material such as AlₙIn₁₋ₙ₋ₘGaₙN, wherein in each case 0≤n≤1, 0≤m≤1, and n+m≤1. The semiconductor layer sequence may include dopants and additional constituents. However, for simplicity only the key constituents of the semiconductor layer sequence, that is to say Al, Ga, In, and N, are specified, even though these may be partly replaced and/or supplemented by small amounts of other substances. More particularly, the semiconductor layer sequence is formed from InGaN.

The semiconductor layer sequence includes an active layer that has at least one p-n junction and/or one or more quantum well structures. When the illumination device is in operation, electromagnetic radiation is generated in the active layer. A wavelength or the emission maximum of the radiation is optionally in the ultraviolet and/or visible region, in particular at wavelengths between 300 nm and 460 nm inclusive.

In at least one embodiment, the illumination device is a light-emitting diode (LED), in particular a conversion LED. The illumination device is then optionally configured to emit white or colored light.

In combination with the phosphor present in the illumination device, the illumination device is optionally configured to emit yellow light in full conversion or white light in partial or full conversion. As a consequence of the high overlap of the secondary radiation of the phosphor with the eye sensitivity curve, the component exhibits high luminous efficacy of the overall radiation.

The illumination device includes a conversion element. More particularly, the conversion element comprises the phosphor or consists of the phosphor. The phosphor at least partly or fully converts the electromagnetic primary radiation into electromagnetic secondary radiation. The peak wavelength of the secondary radiation is in particular between 530 nm and 550 nm inclusive, such as between 535 nm and 545 nm inclusive, and thus in the yellow region of the electromagnetic spectrum.

In at least one embodiment, the conversion element or illumination device includes no further phosphor besides the phosphor. The conversion element may also consist of the phosphor. The phosphor may in this case be configured for complete conversion of the primary radiation. In this embodiment, the overall radiation of the illumination device is in the yellow region of the electromagnetic spectrum.

In at least one embodiment, the overall radiation of the illumination device is a white mixed radiation. The illumination device emitting a white mixed radiation may optionally comprise no further phosphor besides the phosphor. The phosphor is in this case configured for partial conversion of the primary radiation. The peak wavelength of the primary radiation is here optionally in the blue region of the visible spectrum, for example between 400 nm and 460 nm. Overlap of the blue primary radiation and yellow secondary radiation results in white overall radiation from the illumination device. The device is a “single-phosphor conversion”. Such illumination devices are used particularly in general lighting, for example in street lighting.

In at least one embodiment, the conversion element includes a second and/or third phosphor besides the phosphor. The conversion element may comprise further phosphors besides the phosphor and second and third phosphors. The phosphors are for example embedded in a matrix material. Alternatively, the phosphors may also be present in a converter ceramic.

The illumination device may include a second phosphor for the emission of radiation from the green region of the spectrum.

The green region of the spectrum can be understood as meaning in particular the region of the electromagnetic spectrum between 525 nm and 560 nm inclusive.

Additionally or alternatively, the illumination device may include a third phosphor. The third phosphor may be configured for the emission of radiation from the red region of the spectrum. In other words, the illumination device may then have at least three phosphors: the yellow-emitting phosphor, a red-emitting phosphor, and a green-emitting phosphor. The illumination device is configured for full conversion or partial conversion, the primary radiation optionally being selected from the UV to blue region of the spectrum in the case of full conversion and from the blue region in the case of partial conversion. The resulting overall radiation of the illumination device is then in particular a white mixed radiation.

The presence of a second and/or third phosphor in addition to the phosphor may in particular increase the color rendering index (CRI). Further phosphors besides the second and third phosphor are in particular not excluded here. The higher the color rendering index, the truer or more natural the perceived color impression.

Illumination devices that emit a white overall radiation with high CRI values are used, for example, in lighting for living spaces, museums, and stadia.

The red region of the spectrum can be understood as meaning the region of the electromagnetic spectrum between 620 nm and 780 nm.

### Working Example

A working example WE1 of the phosphor having the empirical formula Ca₃Li₄Si₃O₈N₂:Eu²⁺ was produced as follows: CaO, Li₃N, Si₃N₄, SiO₂, and Eu₂O₃ were mixed and the mixture was heated in a nickel crucible under N₂ containing 7.5% H₂ to a temperature of between 700° C. and 1000° C., held at this temperature for 2 to 15 hours, and then cooled.

The starting material weights are shown in Table 1 below.

TABLE 1

| Starting material | Mass/g |
|---|---|
| Si₃N₄ | 1.893 |
| CaO | 4.450 |
| Li₃N | 0.940 |
| SiO₂ | 2.432 |
| Eu₂O₃ | 0.285 |

The phosphor starting materials are commercially available, stable, easy to handle, and also very inexpensive. The simple synthesis at comparatively low temperatures makes the phosphor very inexpensive to produce and thus also economically attractive.

In particular, the phosphor is more inexpensive to produce than (Y, Gd, Tb, Lu)₃Al₅O₁₂:Ce, since the use of high-priced rare earth elements (Y, Gd, Tb, Lu, and Ce in (Y,Gd,Tb,Lu)₃Al₅O₁₂:Ce) can be restricted to Eu. Garnet phosphors are moreover usually synthesized at temperatures between 1400° C. and 1600° C. The synthesis of the new phosphor is therefore comparatively energy-saving and production costs are kept within limits.

Table 2 below shows crystallographic data for Ca₃Li₄Si₃O₈N₂:Eu (WE1). The phosphor crystallizes in the orthorhombic crystal system in the space group Pbcn.

TABLE 2

| | WE1 |
|---|---|
| Empirical formula | Ca₃Li₄Si₃O₈N₂:Eu |
| Molar mass | 388.3 g/mol |
| Crystal system | orthorhombic |
| Space group | Pbcn (no 60) |
| Lattice parameters | |
| a/Å | 17.451(1) |
| b/Å | 4.9606(13) |
| c/Å | 10.024(1) |
| Cell volume/nm³ | 867.8(3) |
| Density ρ/g cm⁻³ | 2.9719 |
| T/K | 293 |
| Radiation | Cu-Kα (λ = 1.542 Å) |
| Measurement range | 5.6 < θ < 74.4 |
| Total reflections | 10034 |
| Independent reflections | 886 |
| Measured reciprocal space | 5.6 < θ < 74.4 |
| Number of parameters | 83 |
| Rᵢₙₜ, Rσ | 0.1208, 0.0488 |
| Δρₘₐₓ, Δρₘᵢₙ/eÅ⁻³ | 0.53/−0.71 |
| R₁ (obs/all) | 0.037/0.069 |
| wR₂ (obs/all) | 0.077/0.088 |
| GooF (obs/all) | 1.44/1.33 |

Table 3 below shows the atomic parameters for Ca₃Li₄Si₃O₈N₂:Eu (WE1).

TABLE 3

| | | | | Occupa- | |
|---|---|---|---|---|---|
| Atom | x | y | z | tion | Uᵢₛₒ |
| Ca1 | ½ | 0 | 0 | 1 | 0.0128(4) |
| Ca2 | 0.3165(1) | −0.4519(2) | −0.2277(1) | 1 | 0.0158(3) |
| Si1 | 0.7032(8) | 0.0427(3) | −0.0237(1) | 1 | 0.0099(3) |
| Si2 | ½ | 0.5124(4) | −¼ | 1 | 0.0097(5) |
| O1 | 0.4413(2) | 0.2975(8) | 0.1638(4) | 1 | 0.0153(10) |
| O2 | 0.4497(2) | 0.3196(8) | −0.1513(4) | 1 | 0.0141(10) |
| O3 | 0.3071(2) | 0.0778(8) | −0.3123(3) | 1 | 0.0153(10) |
| O4 | 0.6256(2) | 0.1705(7) | 0.0480(4) | 1 | 0.0136(10) |
| N1 | 0.2851(2) | 0.2888(8) | −0.0224(4) | 1 | 0.0128(11) |
| Li1 | 0.3935(4) | 0.4562(15) | 0.0042(7) | 1 | 0.0042(14) |
| Li2 | 0.3990(5) | 0.0165(16) | −0.2241(8) | 1 | 0.0089(15) |

The crystal structure and the crystallographic data shown in Tables 2 and 3 were determined by X-ray diffraction experiments on single crystals and powders of the phosphor. As can be seen from Table 3, the crystal structure contains two crystallographically distinct Ca atoms (Ca1, Ca2), two crystallographically distinct Si atoms (Si1, Si2), two crystallographically distinct Li atoms (Li1, Li2), four crystallographically distinct O atoms (O1, O2, O3, O4), and an N atom.

Tables 4.1 and 4.2 below show anisotropic displacement parameters for Ca₃Li₄Si₃O₈N₂:Eu (WE1).

TABLE 4.1

| Atom | U₁₁ | U₂₂ | U₃₃ |
|---|---|---|---|
| Ca1 | 0.0128(6) | 0.0128(7) | 0.0127(6) |
| Ca2 | 0.0151(5) | 0.0157(5) | 0.0165(5) |
| Si1 | 0.0096(6) | 0.0087(6) | 0.0112(6) |
| Si2 | 0.0111(8) | 0.0077(9) | 0.0104(8) |
| O1 | 0.0176(19) | 0.0140(18) | 0.0144(17) |
| O2 | 0.0145(18) | 0.0147(17) | 0.0130(16) |
| O3 | 0.0159(19) | 0.0169(17) | 0.0129(16) |
| O4 | 0.0145(18) | 0.0095(17) | 0.0167(16) |
| N1 | 0.013(2) | 0.0065(17) | 0.019(2) |
| Li1 | 0.0151(5) | 0.0157(5) | 0.0165(5) |
| Li2 | 0.0096(6) | 0.0087(6) | 0.0112(6) |

TABLE 4.2

| Atom | U₂₃ | U₁₃ | U₁₂ |
|---|---|---|---|
| Ca1 | 0.0007(6) | −0.0013(5) | 0.0000(6) |
| Ca2 | −0.0005(4) | −0.0003(4) | −0.0002(5) |
| Si1 | −0.0001(5) | −0.0003(5) | 0.0004(5) |
| Si2 | 0 | 0.0002(7) | 0 |
| O1 | −0.0060(16) | −0.0020(16) | −0.0023(15) |
| O2 | −0.0001(16) | 0.0024(15) | 0.0009(15) |
| O3 | 0.0010(15) | −0.0002(13) | −0.0011(15) |
| O4 | −0.0003(14) | 0.0025(15) | −0.0011(15) |
| N1 | 0.0021(17) | 0.0039(18) | −0.0006(17) |
| Li1 | −0.0005(4) | −0.0003(4) | −0.0002(5) |
| Li2 | −0.0001(5) | −0.0003(5) | 0.0004(5) |

### BRIEF DESCRIPTION OF THE DRAWINGS

Further advantageous embodiments and developments arise from the working examples described below in conjunction with the figures. The accompanying drawings serve to afford an understanding of various embodiments. The drawings illustrate embodiments and together with the description serve to elucidate same. Further embodiments and numerous advantages from among those intended are evident directly from the following detailed description. The elements and structures shown in the drawings are not necessarily illustrated in a manner true to scale with respect to one another. Identical reference signs refer to identical or mutually corresponding elements and structures.

FIGS. 1 and 5 show emission spectra.

FIG. 2 shows a Kubelka-Munk function.

FIGS. 3a, 3b, 3c, 3d, 3f, and 3g show sections of the crystal structure of a working example of the phosphor.

FIG. 4 shows a Rietveld refinement of an X-ray powder diffractogram of a working example of the phosphor.

FIGS. 6, 7, and 8 show conversion LEDs.

### DETAILED DESCRIPTION

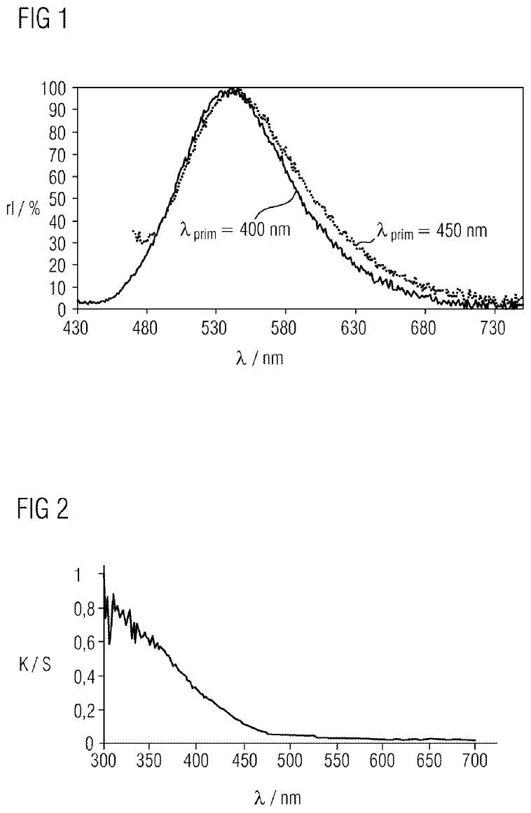

FIG. 1 shows two emission spectra of Ca₃Li₄Si₃O₈N₂:Eu²⁺ (WE1). The wavelength in nanometers is plotted on the x axis and the relative intensity in percent on the y axis. For the measurement of the emission spectra, the phosphor was excited both with primary radiation having a peak wavelength of 400 nm and with primary radiation having a peak wavelength of 450 nm. The phosphor has a peak wavelength in the yellow region of the electromagnetic spectrum. On excitation with primary radiation having a peak wavelength of 400 nm, the peak wavelength of the secondary radiation is at 540 nm, the dominant wavelength of the secondary radiation is at 557 nm, the full width at half maximum is 94 nm, and the color locus in the CIE color space is at CIE-x=0.348 and CIE-y=0.555. Excitation with primary radiation having a peak wavelength of 450 nm results in a broadening of the emission band to a full width at half maximum of 100.8 nm. The phosphor may be present as the sole phosphor in an illumination device or conversion LED. The primary radiation is here optionally in the visible, blue region of the electromagnetic spectrum, such as between 400 and 460 nm. Overlap of the primary and secondary radiation results in a white overall radiation or mixed radiation.

FIG. 2 shows a plot of a normalized Kubelka-Munk function (K/S) against the wavelength A in nm for Ca₃Li₄Si₃O₈N₂:Eu²⁺ (WE1). K/S was calculated for this as follows:

K/S=(1−R_{inf})²/2R_{inf}, wherein R_{inf} corresponds to the diffuse reflection (remission) of the phosphor.

From FIG. 2 it can be seen that the K/S maximum for Ca₃Li₄Si₃O₈N₂:Eu²⁺ (WE1) is at about 300 nm. High K/S values mean high absorbance in this range. The phosphor can be efficiently excited with primary radiation from around 300 nm to 470 nm.

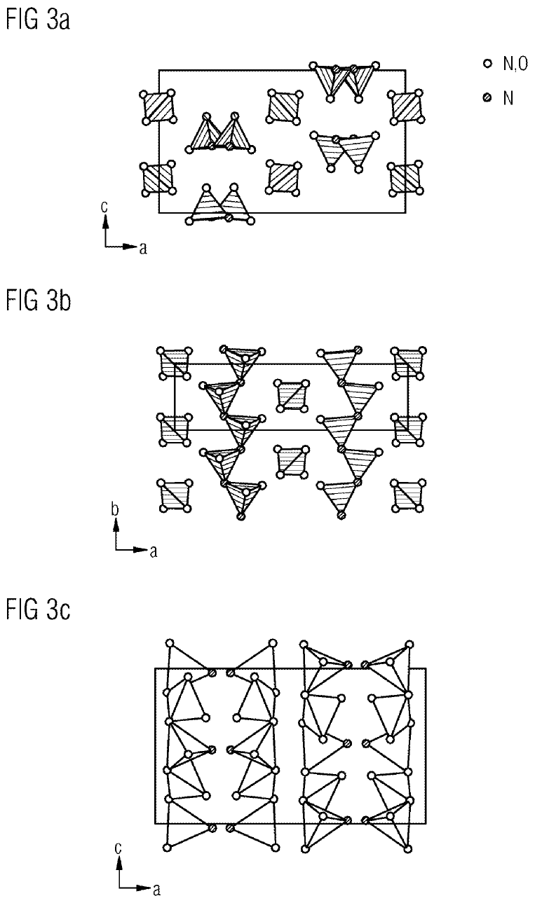

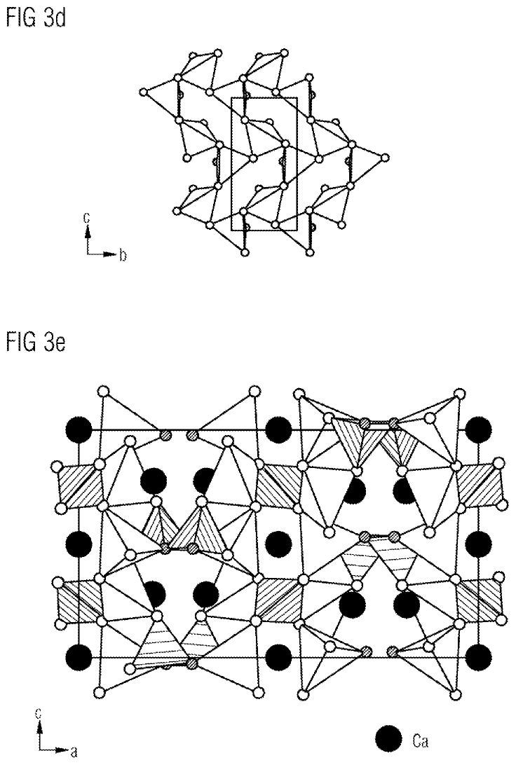

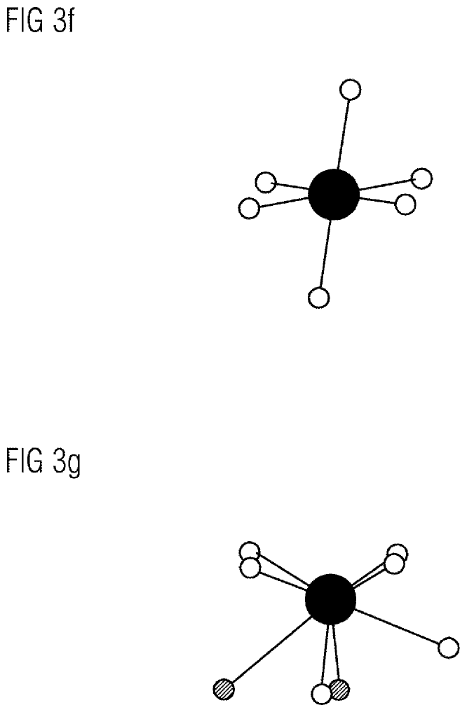

FIGS. 3a and 3b show the linking of Si(O,N)₄ tetrahedra in the crystal structure (orthorhombic, space group Pbcn) of Ca₃Li₄Si₃O₈N₂:Eu²⁺ along the b axis of a unit cell within the crystal structure (FIG. 3a) and along the c axis of a unit cell within the crystal structure (FIG. 3b). Si(1) atoms (see Table 3) form SiO₂N₂ tetrahedra that are linked at their corners via N atoms of the SiO₂N₂ tetrahedra, forming zigzag chains along the b axis. Si(2) atoms (see Table 3) form SiO₄ tetrahedra that are present in isolation, i.e. are not linked to any other tetrahedra. Oxygen and/or nitrogen atoms form the corners of the Si(O,N)₄ tetrahedra, with the Si atoms positioned in the centers of the tetrahedra.

FIGS. 3c and 3d show the linking of Li(O,N)₄ tetrahedra in the crystal structure (orthorhombic, space group Pbcn) of Ca₃Li₄Si₃O₈N₂:Eu²⁺ along the b axis of a unit cell (FIG. 3c) and along the a axis of a unit cell (FIG. 3d). Li(1) atoms (see Table 3) form LiO₃N tetrahedra and Li(2) atoms form LiO₄ tetrahedra. The LiO₃N and LiO₄ tetrahedra are positioned alternately and linked to one another at their corners via oxygen atoms, forming layers of six-membered rings in the bc plane (FIG. 3d). Each tetrahedron is here part of three six-membered rings. Oxygen and/or nitrogen atoms form the corners of the Li(O,N)₄ tetrahedra, with the Li atoms positioned in the centers of the tetrahedra.

FIG. 3e shows the linking of the Si(O,N)₄ and Li(O,N)₄ tetrahedra shown in FIGS. 3a, 3b, 3c, and 3d. The section of the crystal structure is shown along the b axis. The Ca atoms occupy two different channels formed by Si(O,N)₄ and Li(O,N)₄ tetrahedra. Ca(1) atoms (see Table 3) are surrounded by six oxygen atoms in a distorted octahedral arrangement and Ca(2) atoms (see Table 3) are surrounded by six oxygen atoms and two nitrogen atoms in the form of a distorted square antiprism.

FIG. 3f shows the coordination sphere of Ca(1) atoms (see Table 3) in the crystal structure of Ca₃Li₄Si₃O₈N₂:Eu²⁺. A Ca (1) atom is here surrounded by six oxygen atoms in a distorted octahedral arrangement.

FIG. 3g shows the coordination sphere of Ca(2) atoms (see Table 3) in the crystal structure of Ca₃Li₄Si₃O₈N₂:Eu²⁺. A Ca (2) atom is here surrounded by six oxygen atoms and two nitrogen atoms in the form of a distorted square antiprism.

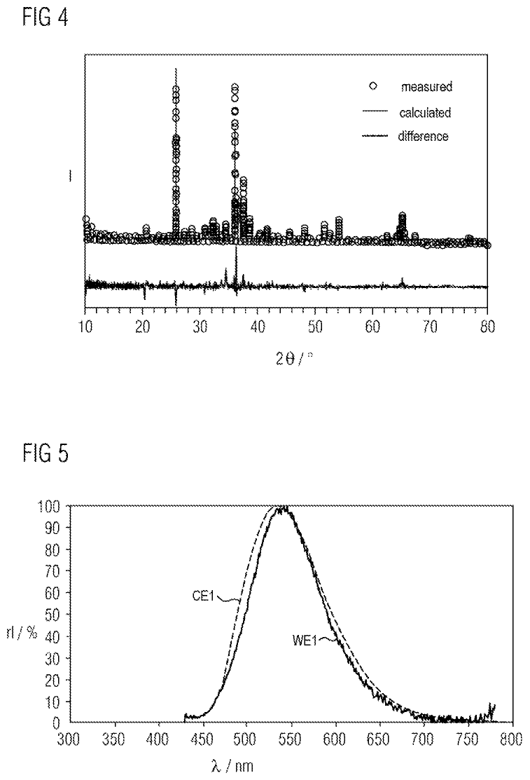

A crystallographic evaluation is given in FIG. 4. FIG. 4 shows a Rietveld refinement of the X-ray powder diffractogram of Ca₃Li₄Si₃O₈N₂:Eu²⁺. The superposition of the measured reflections with the calculated reflections for Ca₃Li₄Si₃O₈N₂:Eu²⁺ crystallizing in the orthorhombic space group Pbcn and the differences between the measured and calculated reflections are shown.

FIG. 5 shows a comparison of the emission spectrum of Ca₃Li₄Si₃O₈N₂:Eu²⁺ (WE1) on excitation with primary radiation having a peak wavelength of 400 nm and of Lu₃Al₅O₁₂:Ce³⁺ (CE1) on excitation with primary radiation having a peak wavelength of 460 nm. The optical data based on these emission spectra are shown in Table 5 below.

TABLE 5

| | Lu₃Al₅O₁₂:Ce³⁺ | Ca₃Li₄Si₃O₈N₂:Eu²⁺ |
|---|---|---|
| | (CE1) | (WE1) |
| λ_{dom}/nm | 558 | 557 |
| FWHM/nm | 108 | 94 |
| Luminous efficacy | 449 | 458 |
| (LER) | | |
| Φᵥ/Φₑ/lmW⁻¹ | | |
| LER relative to | 100% | 102% |
| LU₃Al₅O₁₂:Ce³⁺ | | |

As can be seen from Table 5, Ca₃Li₄Si₃O₈N₂:Eu²⁺ (WE1) has a significantly smaller full width at half maximum than Lu₃Al₅O₁₂:Ce³⁺ (CE1). The smaller full width at half maximum means that the luminous efficacy of the phosphor is also much higher and increased by 2% compared to the luminous efficacy of Lu₃Al₅O₁₂:Ce³⁺ (CE1).

The inventors have thus succeeded in providing not only an alternative, but also a yellow-emitting phosphor that can be produced more efficiently and more inexpensively than garnet phosphors and is also very stable.

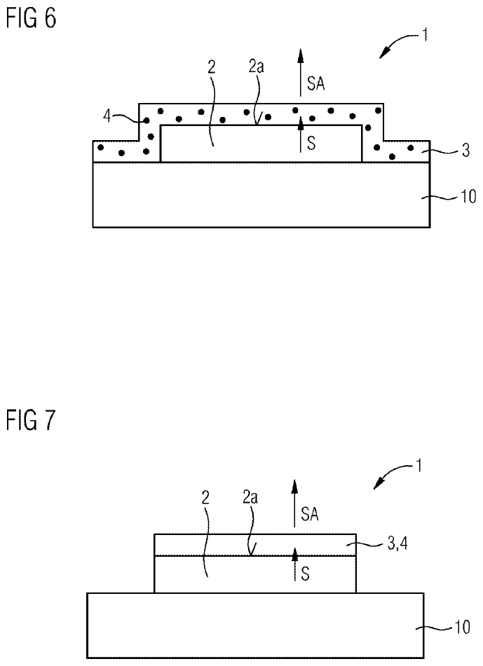

FIGS. 6 to 8 each show schematic side views of different embodiments of the illumination devices described here, in particular conversion LEDs.

The conversion LEDs in FIGS. 6 to 8 include at least one phosphor. In addition, one further phosphor or a combination of phosphors may be present in the conversion LED. The additional phosphors are known to the those skilled in the art and are therefore not mentioned explicitly at this point.

The conversion LED depicted in FIG. 6 has a semiconductor layer sequence 2 disposed atop a substrate 10. The substrate 10 may, for example, be designed to be in reflective form. Disposed atop the semiconductor layer sequence 2 is a conversion element 3 in the form of a layer. The semiconductor layer sequence 2 has an active layer (not shown) which, when the conversion LED is in operation, emits primary radiation having a wavelength 300 nm and 460 nm inclusive. The conversion element 3 is positioned in the beam path of the primary radiation S. The conversion element 3 comprises a matrix material, for example a silicone, epoxy resin or hybrid material, and particles of the phosphor 4, for example Ca₃Li₄Si₃O₈N₂:Eu²⁺.

For example, the phosphor 4 has an average particle size of 10 μm. When the conversion LED is in operation, the phosphor 4 is capable of converting the primary radiation S at least partly or fully into secondary radiation SA in the yellow region of the spectrum. In the conversion element 3, the phosphor 4 is distributed homogeneously in the matrix material within the manufacturing tolerance.

Alternatively, the phosphor 4 may also be distributed in the matrix material with a concentration gradient.

Alternatively, the matrix material may also be absent, such that the phosphor 4 takes the form of a ceramic converter.

The conversion element 3 has been applied over the full area of the radiation exit face 2a of the semiconductor layer sequence 2 and of the side faces of the semiconductor layer sequence 2, and is in direct mechanical contact with the radiation exit face 2a of the semiconductor layer sequence 2 and the side faces of the semiconductor layer sequence 2. The primary radiation S may also exit via the side faces of the semiconductor layer sequence 2.

The conversion element 3 may be applied, for example, by injection molding, injection compression molding or spray coating methods. In addition, the conversion LED has electrical contacts (not shown here), the formation and disposition of which are known to those skilled in the art.

Alternatively, it is also possible for the conversion element to have been prefabricated and applied to the semiconductor layer sequence 2 by means of a “pick-and-place” process.

FIG. 7 shows a further working example of a conversion LED 1. The conversion LED 1 has a semiconductor layer sequence 2 atop a substrate 10. The conversion element 3 has been formed atop the semiconductor layer sequence 2. The conversion element 3 takes the form of platelets. The platelet may consist of particles of the inventive phosphor 4 that have been sintered together and hence be a ceramic platelet, or the platelet includes, for example, glass, silicone, an epoxy resin, a polysilazane, a polymethacrylate or a polycarbonate as matrix material with particles of the phosphor 4 embedded therein.

The conversion element 3 has been applied over the full area of the radiation exit face 2a of the semiconductor layer sequence 2. More particularly, no primary radiation S exits via the side faces of the semiconductor layer sequence 2; rather, it exits predominantly via the radiation exit face 2a. The conversion element 3 may have been applied atop the semiconductor layer sequence 2 by means of a bonding layer (not shown), composed for example of silicone.

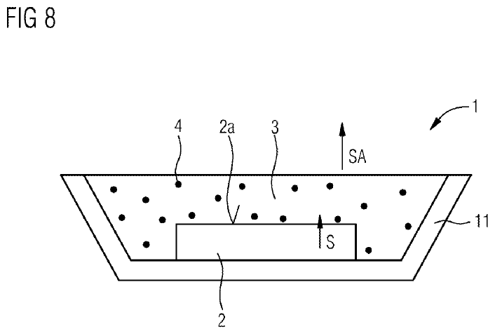

The conversion LED 1 depicted in FIG. 8 has a housing 11 with a recess. A semiconductor layer sequence 2 having an active layer (not shown) is disposed within the recess. When the conversion LED is in operation, the active layer emits primary radiation S with a wavelength of 300 nm to 460 nm inclusive.

The conversion element 3 takes the form of an encapsulation of the layer sequence in the recess and comprises a matrix material, for example a silicone, and a phosphor 4, for example Ba₃Li₇Al₃O₁₁:Eu. When the conversion LED 1 is in operation, the phosphor 4 converts the primary radiation S at least partly into secondary radiation SA. Alternatively, the phosphor converts the primary radiation S fully into secondary radiation SA.

It is also possible that the phosphor 4 in the working examples in FIGS. 6 to 8 is arranged in the conversion element 3 spaced apart from the semiconductor layer sequence 2 or the radiation exit face 2a. This may be achieved for example by sedimentation or by applying the conversion layer atop the housing.

For example, by contrast with the embodiment depicted in FIG. 8, the encapsulation may consist solely of a matrix material, for example silicone, with application, atop the encapsulation, spaced apart from the semiconductor layer sequence 2, of the conversion element 3 as a layer atop the housing 11 and atop the encapsulation.

The working examples and features thereof that have been described in conjunction with the figures may in further working examples also be combined with one another, even when such combinations are not shown explicitly in the figures. In addition, the working examples described in conjunction with the figures may have additional or alternative features in accordance with the description in the general part.

This patent application claims the priority of German patent application 10 2018 004 827.7, the disclosure content of which is hereby incorporated by reference.

### LIST OF REFERENCE SYMBOLS

1 Illumination device or conversion LED
2 Semiconductor layer sequence or semiconductor chip
2a Radiation exit face
3 Conversion element
4 Phosphor
10 Substrate
11 Housing
S Primary radiation
SA Secondary radiation
LED Light-emitting diode
LER Luminous efficacy
FWHM Full width at half maximum
λ_{dom} Dominant wavelength
λₚₑₐₖ Peak wavelength
λₚᵣᵢₘ Peak wavelength of the primary radiation
ppm Parts per million
WE Working example
CE Comparative example
g Gram
I Intensity
mol % Mole percent
nm Nanometer
° C. Degree Celsius
CIE-x, CIE-y Color coordinates in the CIE color space (1931)

1. A phosphor having the general empirical formula X₃X₄Si₃O₈N₂:E, wherein
X=Mg, Ca, Sr, Ba, Zn, or combinations thereof;
A=Li, Na, K, Rb, Cs, Cu, Ag, or combinations thereof; and
E=Eu, Ce, Yb, Mn, or combinations thereof.

2. The phosphor as claimed in claim 1, wherein X=Mg, Ca, Sr, Ba.

3. The phosphor as claimed in claim 1, wherein the general empirical formula is (Ca₁₋ₓX⁺ₓ)₃X₄Si₃O₈N₂:E, wherein
X⁺=Mg, Ba, Sr, or combinations thereof;
A=Li, Na, K, Rb, Cs, Cu, Ag, or combinations thereof;
E=Eu, Ce, Yb, Mn, or combinations thereof; and
0≤x≤0.25.

4. The phosphor as claimed in claim 3, wherein:
X⁺=Ba Sr;
A=Li, Na, K, Rb, Cs; and
0≤x≤0.25.

5. The phosphor as claimed in claim 1, wherein the general empirical formula is Ca₃X₄Si₃O₈N₂:E, wherein:
A=Li, Na, K, Rb, Cs; and
E=Eu, Ce, Yb, Mn.

6. The phosphor as claimed in claim 1, wherein A=Li.

7. The phosphor as claimed in claim 1, wherein E=Eu.

8. The phosphor as claimed in claim 1, wherein the phosphor crystallizes in an orthorhombic crystal system.

9. The phosphor as claimed in claim 1, wherein the phosphor crystallizes in an orthorhombic space group Pbcn.

10. An illumination device comprising a phosphor as claimed in claim 1.

11. The illumination device as claimed in claim 10, further comprising:
a semiconductor layer sequence configured to emit electromagnetic primary radiation; and
a conversion element comprising the phosphor; and wherein the conversion element at least partly converts the electromagnetic primary radiation into electromagnetic secondary radiation.

12. The illumination device as claimed in claim 11, wherein the illumination device is configured to emit an overall white radiation.
